(19) United States
(12) Patent Application Publication
(10) Pub. No.: US 2010/0117660 A1
(43) Pub. Date: May 13, 2010

(54) CABLE FOR A CAPACITIVE PROXIMITY SENSOR

(76) Inventors: Malcolm F. Douglas, Wales (GB); David Cook, Berkshire (GB); Richard A. Loyd, Oxfodshire (GB)

Correspondence Address: 3M INNOVATIVE PROPERTIES COMPANY, PO BOX 33427, ST. PAUL, MN, 55133-3427, US

(21) Appl. No.: 12/523,255

(22) PCT Filed: Jan. 19, 2007
(86) PCT No.: PCT/US07/01693

§ 371 Date: Jan. 7, 2010

(51) Int. Cl. G01R 27/26

(52) U.S. Cl. 324/658

(57) ABSTRACT

A capacitive proximity sensor assembly comprises: (i) a capacitive proximity sensor (1) for mounting to a body for sensing external objects, the sensor comprising a dielectric substrate (2) having front and rear major surfaces which, in use of the sensor, face respectively outward from and towards the body; a sensor conductor (3) on the front major surface; and a guard conductor on at least one of the major surfaces to provide an electrical shield for the sensor conductor; and (ii) a cable (16) for transmitting electrical signals from the sensor (1) to an electronic control unit; the cable comprising a dielectric film substrate having, on a first major surface thereof, a first electrical conductor (13) that is connected to the sensor conductor (3) for transmitting electrical signals therefrom and, on both major surfaces thereof, an electrically-conductive layer (14) that is connected to the guard conductor to provide an electrical shield for the said first conductor (13).

### FIELD

The present disclosure relates to a capacitive proximity sensor for mounting to a body such as, for example, the rear side and/or bumper of a vehicle, to sense external objects.

### BACKGROUND

Capacitive proximity sensors have been used in various industrial applications for sensing the presence of objects or materials. Various forms of capacitive proximity sensors are known and are suitable for use in different environments and applications including, for example, touch-operated systems, collision-prevention systems, occupancy-detection systems, and security/warning systems. In one field of application, capacitive proximity sensors have been fitted to the rear side and/or bumpers of vehicles so that, when a vehicle is reversed, a warning signal is provided if it approaches an object so that a collision can be safely avoided while still allowing the driver to conveniently position the vehicle close to the object.

WO 01/08925 (AB Automotive Electronics Ltd.) describes a capacitive proximity sensor for a vehicle, which consists of two strips of metal, or other conductive material, insulated from each other and provided on the inside of the bumper of a vehicle. One strip, which faces outwardly from the vehicle, is referred to as the sensor plate and the other strip, which faces inwardly towards the vehicle, is called the guard plate. Both plates are connected to a control unit. The control unit monitors the change that occurs in the capacitance between the sensor plate and (electrical) ground as the vehicle approaches an external object and provides an indication to the driver of the distance between the sensor plate (and, hence, the vehicle) and the object. Various geometries for the sensor plate are described, to increase the sensitivity of the proximity sensor at the corners of the vehicle.

GB-A-2 374 422 (of the same Applicant) describes a modified form of such a capacitive proximity sensor, in which an extra conductive plate is provided to reduce the effect of rainwater on the sensitivity of the sensor. That extra conductive plate, which can be arranged above or below the sensor plate (with respect to ground level), is often referred to as the superguard conductor. More generally, a superguard conductor can be used to address the problem of reducing the sensitivity of a capacitive proximity sensor to very close objects that the sensor is not required to detect.

GB-A-2 400 666 (also of the same Applicant) mentions the manufacture of a capacitive proximity sensor of the type described in WO 01/08925 by screen-printing the sensor and guard plates with conductive ink onto opposite sides of a plastic film substrate. GB-A-2 400 666 also describes that the sensor and guard plates may, as an alternative, be formed from aluminium foil that is laminated to the plastic film substrate.

The present disclosure is concerned with capacitive proximity sensors of the type comprising a dielectric substrate, for example a film, having a sensor conductor on one of its major surfaces and a guard conductor on at least one of its major surfaces to provide an electrical shield for the sensor conductor. Electrical connection of a sensor of that type to an electronic control unit often requires the use of a coaxial cable, to ensure that signals transmitted from the sensor to the control unit are electrically screened against external interference. For example, in the case of a capacitive proximity sensor located on the bumper of a vehicle, the signals transmitted from the sensor need to be electrically screened especially from the grounded body of the vehicle. Conventional coaxial cables are, however, comparatively expensive and, because they tend to be somewhat bulky and rigid, are not always well suited to use with capacitive proximity sensors or to the locations (such as vehicle bumpers) in which the sensors are employed. In the particular case in which a sensor is positioned on a vehicle bumper, it is also important that the physical connection between the coaxial cable and the sensor should be robust enough to withstand shocks, exposure to the weather, and blows from objects thrown up from the road.

In some embodiments, the present disclosure provides a capacitive proximity sensor of the above-mentioned type, a cable that can provide the required electrical screening for signals transmitted from the sensor but is comparatively straightforward and inexpensive to manufacture, is compatible with the sensor as regards its physical characteristics, and can be reliably connected to the sensor in a comparatively simple manner.

In some embodiments, the present disclosure provides a capacitive sensor assembly comprising:

(i) a capacitive proximity sensor for mounting to a body for sensing external objects, the sensor comprising a dielectric substrate having front and rear major surfaces which, in use of the sensor, face respectively outward from and towards the body; a sensor conductor on the front major surface; and a guard conductor on at least one of the major surfaces to provide an electrical shield for the sensor conductor; and

(ii) a cable for transmitting electrical signals from the sensor to an electronic control unit; the cable comprising a dielectric film substrate having, on a first major surface thereof, a first electrical conductor that is connected to the sensor conductor for transmitting electrical signals therefrom and, on both major surfaces thereof, an electrically-conductive layer that is connected to the guard conductor to provide an electrical shield for the said first conductor.

### BRIEF DESCRIPTION OF THE DRAWINGS

Embodiments of the disclosure will be described below, by way of example only, with reference to the accompanying drawings, in which:

FIG. 1 is a diagrammatic plan view of a major surface of a proximity sensor;

FIG. 2 shows an enlarged diagrammatic cross-section on the line 2-2 of FIG. 1;

FIG. 3 is a diagrammatic plan view of a blank that is used in the assembly of a cable for use with the sensor of FIGS. 1 and 2;

FIG. 4 shows an enlarged diagrammatic cross-section on the line 4-4 of FIG. 3;

FIG. 5 is a diagrammatic plan view of a cable made using the blank of FIGS. 3 and 4;

FIG. 6 is an enlarged diagrammatic cross-section on the line 6-6 of FIG. 5;

FIG. 7 illustrates the use of the cable of FIGS. 5 and 6 with the sensor of FIGS. 1 and 2;

FIGS. 8, 9 and 10 are cross-sections, similar to FIG. 6, of modified forms of cable (the cross-section of FIG. 10 being viewed in the opposite direction to those of FIGS. 8 and 9).

### DETAILED DESCRIPTION OF EMBODIMENTS

The term “film substrate” as used herein refers to an article having an extension in two directions which exceed the extension in a third direction, which is essentially normal to said two directions, by a factor of at least 5 and more preferably by at least 10. More generally, the term “film” is used herein to refer to a flexible sheet-like material, and includes not only films but also sheetings, foils, strips, laminates, ribbons and the like.

The term “dielectric” as used herein refers to materials having a specific bulk resistively as measured according to ASTM D 257 of at least 1×10¹² Ohm·centimeter (Ωcm) and more preferably of at least 1×10¹³ Ωcm. The term “electrically-conductive” as used herein refers to materials having a surface resistivity as measured according to ASTM B193-01 of less than 1 Ohm per square centimeter (Ω/cm²).

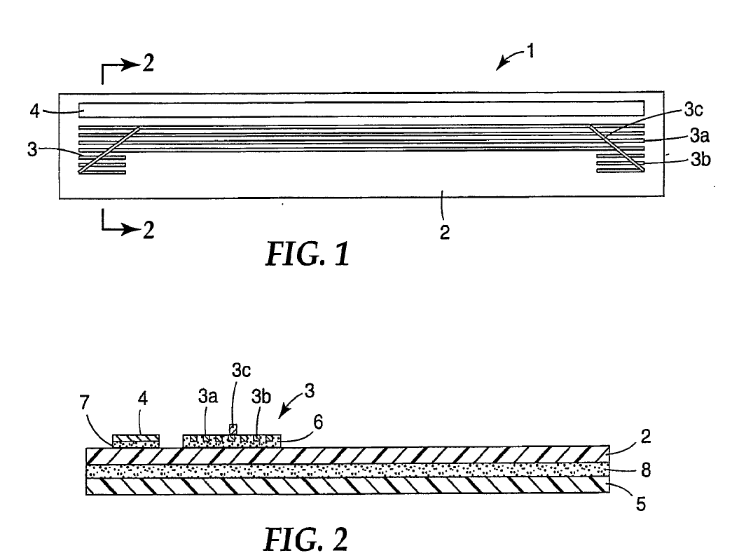

The capacitive proximity sensor 1 of FIGS. 1 and 2 comprises a dielectric film substrate layer 2, the peripheral shape of which is determined mainly by the intended location of the sensor as described further below. In FIG. 1, for the purposes of the present description, the substrate layer 2 is shown diagrammatically as being generally rectangular in shape.

The major surface of the substrate layer 2 shown in FIG. 1 carries a sensor conductor 3 and a superguard conductor 4 that are spaced apart on the surface of the substrate layer, and electrically-isolated from one another by the intervening substrate material. The superguard conductor 4 comprises a flat, electrically-conductive track extending essentially along the length of the substrate layer 2. The sensor conductor 3 exhibits a more complicated design and comprises four, optionally-flattened, conductive tracks 3a extending parallel to one another essentially along the length of the substrate layer 2 and, adjacent both ends of the tracks 3a, three additional parallel (but shorter), optionally-flattened, electrically-conductive tracks 3b forming lobe type regions. The tracks 3a, 3b of the sensor conductor are connected together in both lobe regions by electrically-conductive tracks 3c extending at an angle across the whole array of tracks 3a, 3b.

The opposite major surface of the substrate layer 2, not visible in FIG. 1, carries a guard conductor 5 in the form of an electrically-conductive layer that preferably covers an area of the substrate corresponding in size at least to that occupied, on the other side, by the sensor conductor 3. In the sensor illustrated in FIGS. 1 to 3, the guard conductor 5 essentially fully covers the surface of the main part of the substrate layer 2 to which it is attached. The guard conductor 5 is electrically-isolated from the sensor and superguard conductors 3, 4 by the intervening dielectric substrate layer 2.

In FIG. 2, the sensor, superguard and guard conductors 3, 4, 5 are shown as being attached to the substrate layer 2 by respective adhesive layers 6, 7, 8 although, as described below, that is not essential.

The entire sensor 1 may be encased in a protective cover film (not shown).

The substrate layer 2, with the sensor conductor 3, the guard conductor 5 and the superguard conductor 4, can be attached to any suitable surface, for example the inside of a bumper of a vehicle, to function as a capacitive proximity sensor. To that end, in the case of a vehicle bumper, the substrate layer is positioned with the major surface of FIG. 1 (i.e. the surface carrying the sensor and superguard conductors 3,4) directed outwardly from the vehicle and the other major surface (i.e. the surface carrying the guard conductor 5) directed inwardly towards the vehicle. The conductors 3, 4, 5 are connected to an electronic control unit (not shown) that can monitor the change that occurs in the capacitance between the sensor conductor 3 and (electrical) ground as the vehicle approaches an external object, and thereby provide an indication to the driver of the distance between the sensor conductor (and, hence, the vehicle) and the object. During the monitoring process, the guard conductor 5 acts as a shield to reduce the sensitivity of the sensor conductor 3 to anything behind it in the direction of the body of the vehicle, while an electrical signal is applied to the superguard conductor 4 to make the guard conductor 5 appear even bigger and so minimize the effect, on the signal from the sensor conductor 3, of water drops running over the bumper in rainy weather conditions. Further information on the operation of a capacitive proximity sensor of that type can be obtained from, for example, WO 01/08925, GB-A-2 374 422, and GB-A-2 400 666 mentioned above. The measurement and processing of signals from a capacitive proximity sensor are described, for example, in WO 02/19,524 of the same Applicant.

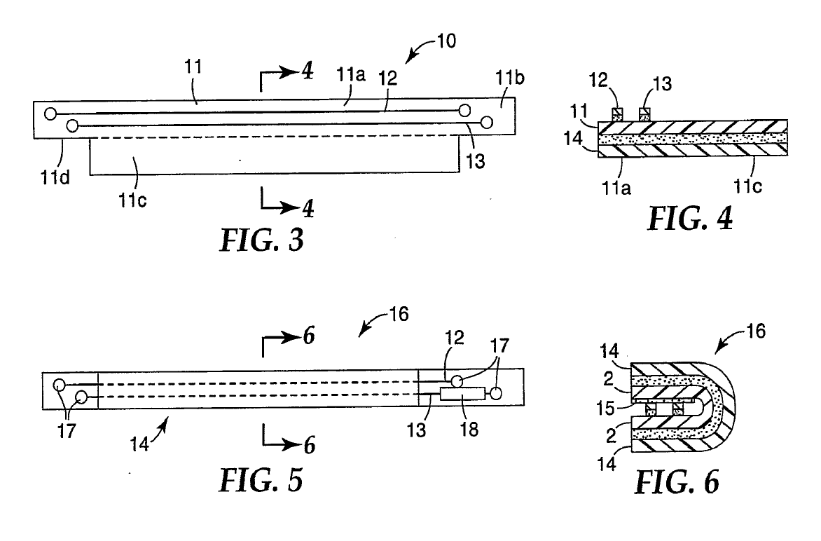

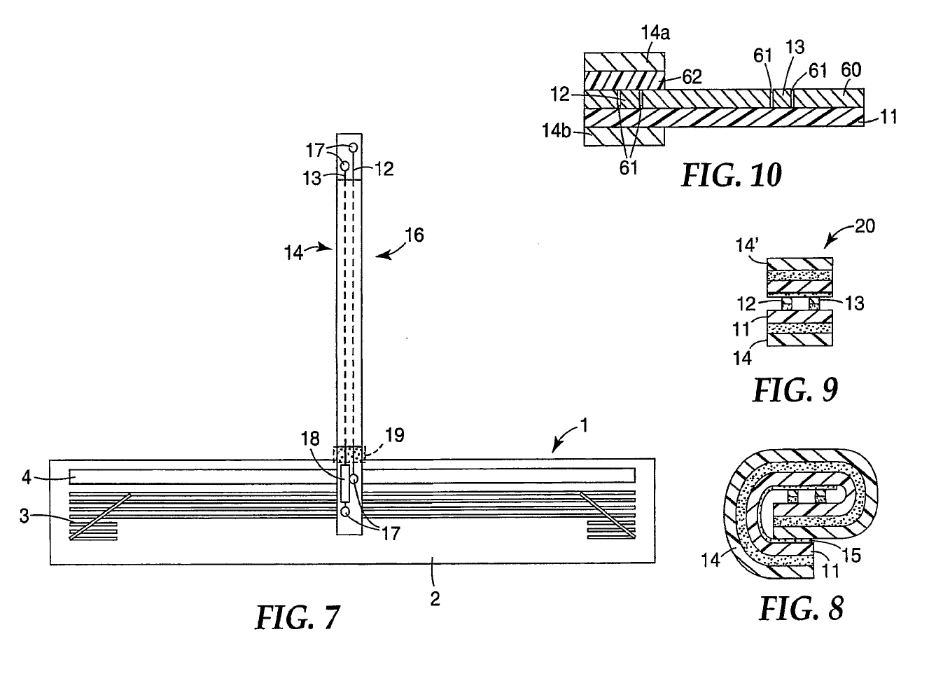

The electrical control unit that receives signals from the sensor 1 is typically located within the vehicle, and a coaxial cable would typically be used to establish the electrical connection between the sensor conductors 3, 4, 5 and the control unit, to ensure that the signals transmitted to the control unit are screened from external interference. As already described, however, conventional coaxial cables are not particularly well suited to being used in this type of environment and an alternative type of cable that is more appropriate will now be described with reference to FIGS. 3 to 5.

FIGS. 3 and 4 show a blank 10 for use in forming the cable. The blank 10 comprises a dielectric film substrate 11, which, in some embodiments, is formed from the same material as the substrate layer 2 of the sensor 1. The main part 11a of the substrate 11 is of rectangular form and has a length corresponding to the required length of the cable. The major surface of this part 11a, shown in FIG. 3, carries two parallel electrically-conductive tracks 12, 13 each of which extends substantially along the whole length of the substrate part, with one track (13) being slightly longer than the other at one end (11b) of the substrate part. The conductive tracks 12, 13 are electrically-isolated from one another by the intervening substrate material. The substrate also has an extension 11c that is shorter than the main part 11a and extends outwardly from one of the longer sides 11d of the latter. Finally, the opposite major surface of the substrate 11 (not visible in FIG. 3) carries an electrically-conductive screen layer 14 that covers the whole area of the main part 11a and the extension 11c. The screen layer 14 is electrically-isolated from the conductive tracks 12, 13 by the intervening material of the substrate 11.

To form the cable, a layer of adhesive 15 (shown in FIG. 6) is applied to the extension 11c of the substrate 11, on the side visible in FIG. 3, and the extension is then folded over to cover the conductive tracks 12, 13. However, because the extension 11c is shorter than the main part 11a of the substrate, the ends of the conductive tracks 12, 13 will remain exposed. The cable 16, which thus has a generally-flat appearance, is then prepared for attachment to the sensor 1 by applying electrically-conductive adhesive pads 17 to the ends of the conductive tracks 12, 13 and covering the extra length of the track 13 with a piece of electrically-insulating adhesive tape 18, as shown in FIG. 5. Finally, the cable 16 is encased in a protective cover film (not shown), leaving the ends of the conductive tracks 12, 13 exposed.

The cable 16 is attached at the end 11b to the sensor 1, by adhering the pad 17 at the end of the longer conductive track 13 to the sensor conductor 3, and the pad 17 at the end of the shorter conductive track 12 to the superguard conductor 4, as shown in FIG. 6. Although the conductive track 13 passes over the superguard conductor 4, the electrically-insulating adhesive tape 18 ensures that they are electrically-isolated from one another. Finally, on the other side of the sensor 1, an electrical connection is established between the guard connector 5 of the sensor and the screen layer 14 of the cable 15 by means of a conductive metal foil tab 19 extending between the two and secured in position by an electrically-conductive adhesive.

The sensor 1 can now be installed in a desired location such as the interior of the bumper of a vehicle. The sensor 1 can be easily attached, for example by an adhesive, to the bumper, and the installation is further assisted by the flexibility of the substrate 2, which facilitates its attachment to a curved surface. It will be understood that the rectangular shape of the substrate 2 shown in the drawings is an example only, and that the substrate would normally be cut to a suitable shape, for example by die-cutting, punching, or laser cutting, having regard to the surface on which it is intended to be mounted. The substrate 2 can also be provided as appropriate with features such as cuts and darts to enable it to be attached to a three-dimensionally curved surface, such as the inner surface of a vehicle bumper, without forming undesirable creases. The attached cable 16, being formed from similar materials to the sensor 1, is equally flexible and can be bent as required to enable it to be connected, at the other end, to the electronic control unit in the vehicle without putting undue strain on the electrical connections at either end. In addition, the electrical characteristics of the cable 16, when formed as described above from similar materials to the sensor 1, have been found sufficient to ensure the integrity of electrical signals transmitted from the sensor to the electronic control unit at frequencies typically employed in capacitive proximity sensors for automotive applications (normally around 25 kHz).

It will be apparent that various modifications could be made to the method of forming the cable 16 without substantially altering its construction. For example, the extension 11c of the cable substrate could be made wider so that it will wrap around the opposite edge of the main part 11a of the substrate as illustrated in FIG. 8, thereby completely enclosing the conductive tracks 12, 13 over most of the length of the cable. Alternatively, the extension 11c of the cable substrate could be omitted, and the cable formed by adhering an equivalent length of a dielectric/screen laminate 20 over the conductive tracks 12, 13 as illustrated in FIG. 9. In that case, the conductive metal foil tab 19 should be adhered to the screen layer 14′ of the laminate 20 as well as to the screen layer 14.

As a further modification, instead of applying a protective cover film to the sensor 1 and the cable 16 separately as described above, the cover film can be applied to the sensor and cable at the same time, after the cable has been electrically-connected to the sensor. In that case, the electrical connection points will also be enclosed within the cover film, reducing the risk of damage.

Suitable materials for use in the sensor 1 and cable 16, and methods in which they can be employed, will now be described.

Suitable materials for the substrate layer 2 of the sensor 1 and the substrate 11 of the cable 16 include, for example, polymeric films and layers, paper films and layers, layers of non-wovens, laminates (such as, for example, polyacrylate foams laminated on both sides with polyolefin films, and papers laminated or jig-welded with polyethylene terephthalate) and combinations thereof. Useful polymeric films and layers include, for example, polyolefin polymers, monoaxially oriented polypropylene (MOPP), biaxially oriented polypropylene (BOPP), simultaneously biaxially oriented polypropylene (SBOPP), polyethylene, copolymers of polypropylene and polyethylene, polyvinylchloride, copolymers having a predominant olefin monomer which may be optionally chlorinated or fluorinated, polyester polymers, polycarbonate polymers, polymethacrylate polymers, cellulose acetate, polyester (e. g. biaxially oriented polyethylene terephthalate), vinyl acetates, and combinations thereof. Useful substrate materials may be subjected to an appropriate surface modification technique including, for example, plasma discharge techniques including corona discharge treatment and flame treatment, mechanical roughening and chemical primers.

The conductive tracks of the sensor conductor 3, and the conductive tracks 12, 13 of the cable 16 may be formed from any suitable electrically-conductive material, for example copper, and may be applied to the substrate 2, 11 by an adhesive as already described. As an alternative, they may be formed by vapour deposition of a suitable metal onto the substrate 2, 11, or by printing/die coating an electrically-conductive ink onto the substrate, or from a foil that is bonded to the substrate. As yet a further alternative, the sensor conductor 3 and the conductive tracks may be formed by removing zones of material from an electrically-conductive layer on the substrate 2, 11, as described in our copending European patent application No. 06001155.8 of 19 Jan. 2006. The sensor conductor 3 may assume a variety of shapes, although a discontinuous arrangement of conductive areas, such as the arrangement of conductive tracks described above, exhibits an especially advantageous sensitivity and may be preferred. It will be appreciated that the number of conductive areas in the sensor conductor 3, and the way in which they are arranged, can be altered as required.

The thickness of the sensor conductor 3 and the conductive tracks 12, 13 (i.e. their height above the substrate 2, 11 on which they are located) may vary widely depending on the method by which they are manufactured. A conductor comprising flattened metal track may have a thickness of between 20 and 200 micrometers (μm), in some case between 25 and 100 μm. A conductor obtained by vacuum metal vapour deposition may be as thin as 200-800 Angstroms (Å) and, in some cases, 300-500 Å. When using an aluminum foil for the conductor, it may have a thickness of from 1-100 μM, in some cases 2-50 μm and, in some cases, 3-30 μm.

The superguard conductor 4 of the sensor 1 may be formed from any suitable electrically-conductive material in any of the ways described above for the sensor conductor 3, and will have a similar resulting thickness. The superguard conductor 4 is not an essential component of the sensor 1 but, if present, may assume a variety of shapes and, in automotive applications, may be arranged (relative to the road level) above or below the sensor conductor 3.

The guard conductor 5 of the sensor 1 and the screen layer 14 of the cable may be formed from any suitable electrically-conductive material, for example aluminium. They may be formed, for example, by adhesively-bonding a metal foil to the relevant substrate 2, 11, or by applying a metallic layer directly to the substrate, for example by vacuum metal vapour deposition. In an advantageous embodiment, in which the guard conductor 5 and screen layer 14 comprise aluminium foil, the substrate material is a filled polypropylene (FPO) film having a thin layer of EVA bonded to it by coextrusion: the EVA layer facilitates the bonding of the aluminium foil to the substrate by heat-lamination.

The thickness of the guard conductor 5 and the screen layer(s) 14, 14′ may vary widely depending on the method by which they are formed on the substrate 2. A metallic layer obtained by vacuum vapour deposition may be as thin as 200-800 Å and, in some cases, 300-500 Å. A metal foil, on the other hand, may have a thickness of from 1-100 μm, in some cases 2-50 μm and, in some cases, 3-30 μm.

The protective cover film (not shown in the drawings) that encases the sensor 1 and the cable 16 is a polymeric film that is applied to the sensor and the cable by, for example, an adhesive or heat-lamination. In some embodiments, the dimensions of the film exceed those of the substrates 2, 11 to provide a border that will form an edge seal around the sensor 1 and cable 16 to protect, in particular, the edges of the guard conductor 5 and the screen layers 14, 14′ against corrosion. The border may have a width of 1-50 mm, in some cases 1-40 mm and, in some cases, 2-20 mm.

Reference is made above to our European patent application No. 06001155.8 of 19 Jan. 2006 entitled “Capacitive sensor film and method for manufacturing the same”, in which the sensor conductor and the superguard conductor (when present) are at least partly surrounded by a front conductor on the same major surface of the substrate layer, being electrically isolated against the front conductor by zones where the front conductor is removed (for example, by laser ablation). If that method is applied to the cable 16, as mentioned above, the conductive tracks 12, 13 are likewise surrounded by a front conductor on the same major surface of the substrate 11, being electrically isolated against the front conductor by zones where the front conductor is removed (for example, by laser ablation). The cable may then have the configuration illustrated in the cross-sectional view of FIG. 10, in which the front conductor is indicated by the reference numeral 60. The conductive tracks 12, 13 are defined within, and electrically isolated from, the surrounding front conductor 60 by zones 61 where the front conductor has been removed e.g. by laser ablation. The cable is completed by the provision of an electrical shield for the conductive track 13 (i.e. the track that, in use, is connected to the sensor conductor 3 of the sensor 1), comprising a layer 14a of conductive material laminated over the strip with an intervening layer of dielectric material 62 and a corresponding layer 14b of conductive material on the opposite side of the substrate layer 11. The electrical shield layers 14a, 62, 14b could extend over the second conductive track 13 also (in the manner illustrated in FIG. 9, but that is not essential. The cable of FIG. 10 may be encased in a protective film (not shown) as described above.

A capacitive proximity sensor as described above with reference to the drawings can be easily installed due to its flexible nature and that of the connector cable, and is especially suited for use in the automotive industry. The use of similar materials and similar manufacturing methods for the sensor and the cable is also advantageous, but is not essential. It will be appreciated, for example, that the cable could be used with other types of capacitive proximity sensors, and is not restricted to use with sensors in which the dielectric substrate is a film material.

It will be understood that the particular configurations shown in the drawings for the sensor and guard conductors and the optional superguard conductor are for the purposes of illustration only and are not an essential feature of the invention. The proximity sensors described herein with reference to the drawings are particularly appropriate for use on vehicle bumpers but the manner in which electrical connection is made between the sensor and guard conductors (and, when present, the superguard conductor) and an electronic control unit, using the flexible cable 16, is applicable to capacitive proximity sensors intended for use in other applications and to capacitive proximity sensors with differently-configured conductors including, for example, those with a sensor conductor of serpentine or spiral form or with two interdigitated sensor conductors, or with a multiplicity of guard conductors.

1-11. (canceled)

12. A capacitive sensor assembly comprising:
(i) a capacitive proximity sensor for mounting to a body for sensing external objects, the sensor comprising a dielectric substrate having front and rear major surfaces which, in use of the sensor, face respectively outward from and towards the body; a sensor conductor on the front major surface; and a guard conductor on at least one of the major surfaces to provide an electrical shield for the sensor conductor; and
(ii) a cable for transmitting electrical signals from the sensor to an electronic control unit; the cable comprising a dielectric film substrate having, on a first major surface thereof, a first electrical conductor that is connected to the sensor conductor for transmitting electrical signals therefrom and, on both major surfaces thereof, an electrically-conductive layer that is connected to the guard conductor to provide an electrical shield for the said first conductor.

13. The sensor assembly of claim 12, wherein the sensor substrate comprises a film.

14. The sensor assembly of claim 12, wherein the electrical shield of the cable is substantially co-extensive with both major surfaces of the cable substrate.

15. The sensor assembly of claim 12, wherein the second major surface of the cable substrate carries an electrically-conductive shielding layer and the cable substrate is folded over so that the electrical conductor on its first major surface is located between two inner layers of cable substrate material and two outer shielding layers.

16. The sensor assembly of claim 12, wherein the second major surface of the cable substrate carries an electrically-conductive shielding layer and the electrical conductor on its first major surface is covered by a dielectric film layer that has an electrically-conductive shielding layer on its outer surface.

17. The sensor assembly of claim 12, wherein the substrate and electrical shield of the cable are formed from the same materials as the substrate and guard conductor, respectively, of the sensor.

18. The sensor assembly of claim 17, wherein the sensor and cable substrates both comprise a polymeric film, and the guard conductor of the sensor and the electrical shield of the cable both comprise a metal foil laminated to the polymeric film.

19. The sensor assembly of claim 12, wherein the cable is connected, at the end remote from the sensor, to an electronic control unit.

20. The sensor assembly of claim 19, wherein the body is a vehicle comprising a vehicle body and a bumper attached to the vehicle body, wherein the sensor is located on an interior surface of the bumper of the vehicle, and the electronic control unit is located within the vehicle body.

21. The sensor assembly of claim 12, wherein the sensor further comprises a superguard conductor on the front major surface of the sensor substrate, and the cable further comprises, on the said first major surface of the cable substrate, a second electrical conductor that is connected to the superguard conductor.

22. The sensor assembly of claim 21, wherein the second major surface of the cable substrate carries an electrically-conductive shielding layer and the cable substrate is folded over so that the first electrical conductor and the second electrical conductor on its first major surface are located between two inner layers of cable substrate material and two outer shielding layers.

23. The sensor assembly of claim 21, wherein the second major surface of the cable substrate carries an electrically-conductive shielding layer and the first electrical conductor and the second electrical conductor on its first major surface are covered by a dielectric film layer that has an electrically-conductive shielding layer on its outer surface.

24. The sensor assembly of claim 21, wherein the cable is connected, at an end remote from the sensor, to an electronic control unit.

25. The sensor assembly of claim 24, wherein the body is a vehicle comprising a vehicle body and a bumper attached to the vehicle body, wherein the sensor is located on an interior surface of the bumper of the vehicle, and the electronic control unit is located within the vehicle body.
